(19) United States
(12) Patent Application Publication
(10) Pub. No.: US 2017/0338141 A1
(43) Pub. Date: Nov. 23, 2017

(54) FLEXIBLE BOARD

(71) Applicants: Shenzhen China Star Optoelectronics Technology Co. Ltd., Shenzhen (CN); Wuhan China Star Optoelectronics Technology Co. Ltd., Wuhan (CN)

(72) Inventor: Yun YU, Shenzhen (CN)

(73) Assignees: Shenzhen China Star Optoelectronics Technology Co. Ltd., Shenzhen (CN); Wuhan China Star Optoelectronics Technology Co. Ltd., Wuhan (CN)

(21) Appl. No.: 14/897,889

(22) PCT Filed: Oct. 29, 2015
(86) PCT No.: PCT/CN2015/093199

§ 371 Date: Dec. 11, 2015

(30) Foreign Application Priority Data
Oct. 23, 2015 (CN) 201510695337.3

(51) Int. Cl. H01L 21/683; B23K 26/00; G02B 5/02

(52) U.S. Cl. CPC H01L 21/6835; G02B 5/0231; G02B 5/0278; B23K 26/0063; H01L 2221/6835; H01L 2221/68377; H01L 2221/68381; H01L 2221/68318

(57) ABSTRACT

A flexible board is disclosed. The flexible board comprises a flexible baseplate, a scattering structure that is arranged on at least one surface of the flexible baseplate, a buffer layer that is arranged at one side of the scattering structure far from the flexible baseplate, and an active layer that is arranged at one side of the buffer layer far from the flexible baseplate. The flexible board according to the present disclosure has an apparent advantage in protecting the active layer.

### CROSS REFERENCE TO RELATED APPLICATION

The present application claims priority of Chinese patent application CN201510695337.3, entitled “Flexible Board” and filed on Oct. 23, 2015, the entirety of which is incorporated herein by reference.

### FIELD OF THE INVENTION

The present disclosure relates to display technical field, and particularly to a flexible board.

### BACKGROUND OF THE INVENTION

According to Laser Lift-Off (LLO) technology, a connection layer between a glass substrate and a flexible baseplate can be decomposed by laser energy, and thus the flexible baseplate can be separated from the glass substrate.

However, during a procedure when the flexible baseplate is separated from the glass substrate through the LLO technology, the laser enters into the glass substrate from one side thereof, passes through the flexible baseplate, a buffer layer, and finally arrives at an active layer. In this case, the energy of the laser would be absorbed by the active layer, and a structure of the active layer would be destroyed by the energy of the laser. Consequently, the components of the flexible board would be destroyed.

### SUMMARY OF THE INVENTION

With respect to the aforesaid technical problem in the prior art. i.e., the structure of the active layer would be destroyed by the energy of the laser when the flexible baseplate is separated from the glass substrate through the LLO technology, the present disclosure provides a flexible board.

According to the present disclosure, the flexible board comprises a flexible baseplate; a scattering structure that is arranged on at least one surface of the flexible baseplate; a buffer layer that is arranged at one side of the scattering structure far from the flexible baseplate; and an active layer that is arranged at one side of the buffer layer far from the flexible baseplate.

In this manner, when the flexible baseplate is separated from one surface of the glass substrate through the LLO technology, a large beam of laser with a high strength enters into the glass substrate from the other surface thereof. The large beam of laser passes through the glass substrate and the flexible baseplate so as to separate the flexible baseplate from the glass substrate, and residual laser, after passing through the flexible baseplate, is scattered by the scattering structure that is arranged on one surface of the flexible baseplate far from the glass substrate. The large beam of laser with a high strength is scattered into multiple small beams of laser with a low strength by the scattering structure. The small beams of laser enter into the buffer layer that is arranged at one side of the scattering structure far from the flexible baseplate, and the laser attenuates gradually in the buffer layer. The small beams of laser attenuates gradually in the buffer layer until disappear, and thus no laser arrives at the active layer that is arranged at one side of the buffer layer far from the flexible baseplate. Therefore, the active layer is not damaged. Of course, according to the technical solution of the present disclosure, even if a small amount of laser arrives at the active layer that is arranged at one side of the buffer layer far from the flexible baseplate, it cannot do harm to the active layer, since the energy of the laser is reduced after scattering and attenuation.

According to one embodiment, the scattering structure comprises more than two scattering elements, and a size of each scattering element has a nanometer to micrometer magnitude. The scattering element with a nanometer to micrometer magnitude has a high scattering effect on the laser.

According to one embodiment, on a surface of the flexible baseplate where the scattering elements are arranged, the scattering elements are arranged without gap thereamong. The scattering elements are arranged adjacent to one another, and thus the plurality of scattering elements as a whole can have a strong scattering effect on the laser coming from the glass substrate. The large beam of laser with a high strength can be scattered into multiple small beams of laser with a low strength by the scattering elements.

According to one embodiment, on a surface of the flexible baseplate where the scattering elements are arranged, the scattering elements are arranged with gap thereamong. In this manner, the arrangement mode of the scattering elements can be regulated flexibly, so that not only the energy of the laser coming from the glass substrate can be scattered, but also the material can be saved, the weight of the product can be reduced, and the production difficulty thereof can be reduced.

According to one embodiment, in any direction of a surface of the flexible baseplate, a width of the gap is ¼ to ½ a size of an adjacent scattering element in a corresponding direction. In this manner, not only the energy of the laser coming from the glass substrate can be scattered better, but also a quantity of the scattering element can be effectively reduced, and the operational procedure and the material used therein can be saved.

According to one embodiment, in a direction perpendicular to a surface of the flexible baseplate, a section of each scattering element has a triangle shape, a rectangle shape, a square shape, a semielliptical shape, a semicircular shape, or a trapezoid shape. The different shape of the section of the scattering element has different influence on the route of the laser, and thus the shape of the scattering element can be selected according to actual condition. The details will be further illustrated hereinafter with reference to different embodiments.

According to one embodiment, the scattering elements are formed on a surface of the flexible baseplate through imprinting technology, photolithography technology, dry etching technology, or wet etching technology. It can be seen that, the specific technology can be selected flexibly.

According to one embodiment, the buffer layer covers all of the scattering elements and is filled in a space between adjacent scattering elements. With this arrangement, the buffer layer can play its role better, because the laser exiting from any surface of the scattering elements at any angle can all enter into the buffer layer for attenuation.

According to one embodiment, in a direction perpendicular to a surface of the flexible baseplate, a thickness of the buffer layer is several times to thousands of times a size of the scattering element in a corresponding direction. With this size arrangement, not only the energy of the scattered laser can be attenuated effectively, but also the thickness and weight of the flexible board would not be increased excessively.

According to one embodiment, the scattering element can also reflect or absorb light. In this manner, the energy of the laser can be prevented from being absorbed by the active layer, and thus the harm to the structure of the active layer can be avoided.

The above technical features can be combined in any suitable manner, or substituted by the equivalent technical features, as long as the purpose of the present disclosure can be achieved.

### BRIEF DESCRIPTION OF THE DRAWINGS

The present disclosure will be illustrated in detail hereinafter with reference to the embodiments and the accompanying drawings. In the drawings:

FIG. 1 schematically shows a structure of a flexible board according to the present disclosure:

FIG. 2 schematically shows a partial structure of a flexible board according to a first embodiment of the present disclosure;

FIG. 3 schematically shows a partial structure of a flexible board according to a second embodiment of the present disclosure:

FIG. 4 schematically shows a partial structure of a flexible board according to a third embodiment of the present disclosure:

FIG. 5 schematically shows a partial structure of a flexible board according to a fourth embodiment of the present disclosure;

FIG. 6 is a laser transmission diagram in a flexible board according to a first embodiment of the present disclosure; and

FIG. 7 is a laser transmission diagram in a flexible board according to a comparative embodiment.

In the drawings, the same components are represented by the same reference signs, and the size of each component does not represent the actual size of the corresponding component.

### DETAILED DESCRIPTION OF THE EMBODIMENTS

The present disclosure will be illustrated further with reference to the drawings.

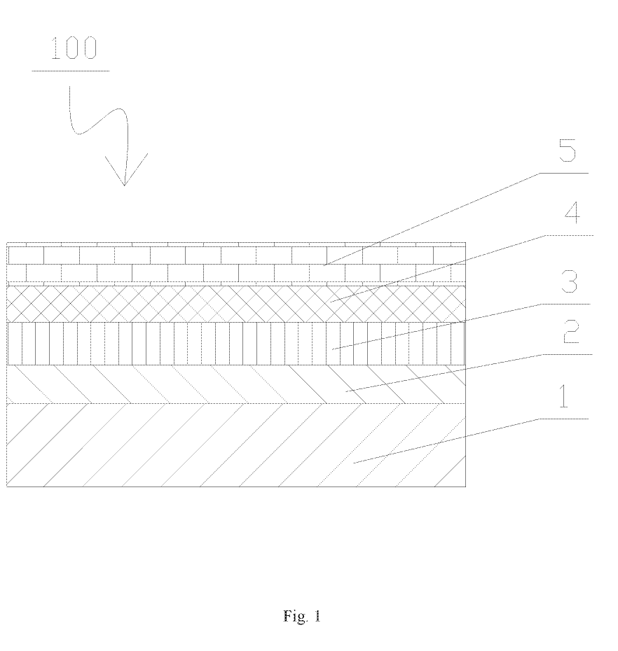

FIG. 1 schematically shows a structure of a flexible board according to the present disclosure. The present disclosure provides a flexible board 100, which comprises a flexible baseplate 2; a scattering structure 3 that is arranged on at least one surface of the flexible baseplate 2 (as shown in FIG. 1, the scattering structure 3 is arranged on the surface of the flexible baseplate 2 far from a glass substrate 1); a buffer layer 4 that is arranged at one side of the scattering structure 3 far from the flexible baseplate 2; and an active layer 5 that is arranged at one side of the buffer layer 4 far from the flexible baseplate 2. It can be seen from FIG. 1 that, the flexible baseplate 2 is arranged on the glass substrate 1.

The flexible board 100 according to the present disclosure is especially applicable for the Laser Lift-Off (LLO) technology. That is, a connection layer between the glass substrate 1 and the flexible baseplate 2 can be decomposed by laser energy, and thus the flexible baseplate 2 can be separated from the glass substrate 1.

Specifically, the scattering structure 3 comprises more than two scattering elements, and a size of each scattering element has a nanometer to micrometer magnitude. The scattering element with a nanometer to micrometer magnitude has a high scattering effect on the laser.

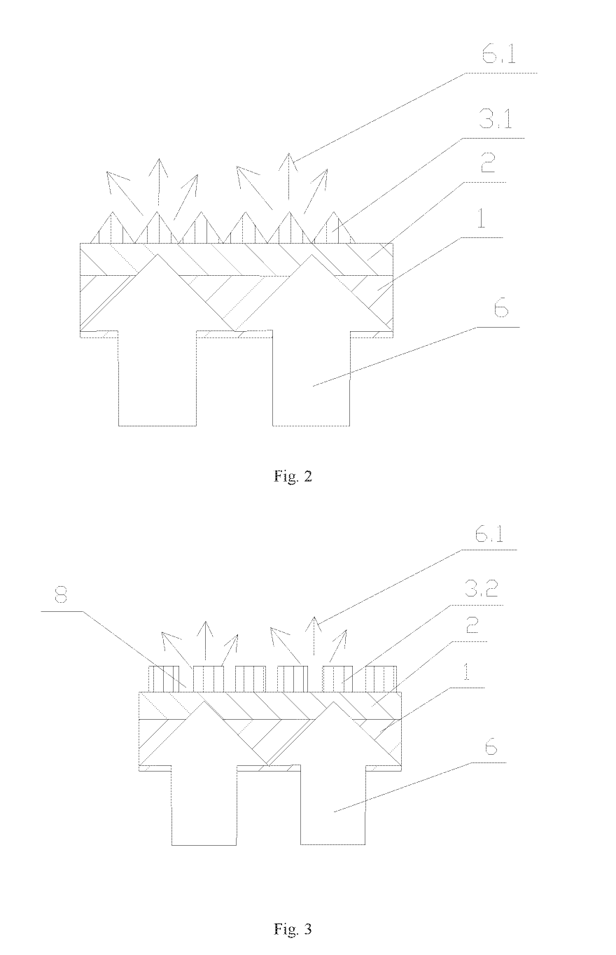

FIG. 2 schematically shows a partial structure of a flexible board according to a first embodiment of the present disclosure. According to the embodiment as shown in FIG. 2, on a surface of the flexible baseplate 2 where the scattering elements 3.1 are arranged (i.e., on the surface of the flexible baseplate 2 far from the glass substrate 1), the scattering elements 3.1 are arranged without gap thereamong. The scattering elements 3.1 are arranged adjacent to one another, and thus the plurality of scattering elements 3.1 as a whole can have a strong scattering effect on the laser 6 coming from the glass substrate 1. It can be seen clearly from FIG. 2 that, the large beam of laser 6 with a high strength can be scattered into multiple small beams of laser 6.1 with a low strength by the scattering elements 3.1.

With respect to the shape of the scattering element 3.1, it can be seen clearly from FIG. 2 that, in a direction perpendicular to a surface of the flexible baseplate 2, a section of each scattering element 3.1 has a triangle shape. A bottom edge of the triangle is affixed to the surface of the flexible baseplate 2. The laser enters into the scattering element 3.1 from the bottom edge thereof, and exits from the other two edges after being scattered by the scattering element 3.1. In this manner, a direction of the light that exits from the scattering element 3.1 can be controlled through regulating the angles of the triangle.

Of course, the scattering elements are not necessarily arranged as the above method, and can also be arranged in other methods. For example, on a surface of the flexible baseplate where the scattering elements are arranged, the scattering elements are arranged with gap thereamong. In this manner, the arrangement mode of the scattering elements can be regulated flexibly, so that not only the energy of the laser coming from the glass substrate 1 can be scattered, but also the material can be saved, the weight of the product can be reduced, and the production difficulty thereof can be reduced.

FIG. 3 schematically shows a partial structure of a flexible board according to a second embodiment of the present disclosure. According to the embodiment as shown in FIG. 3, on a surface of the flexible baseplate 2 where the scattering elements 3.2 are arranged (i.e., on the surface of the flexible baseplate 2 far from the glass substrate 1), the scattering elements 3.2 are arranged with gap 8 thereamong. In this manner, the arrangement mode of the scattering elements 3.2 can be regulated flexibly, so that not only the energy of the laser coming from the glass substrate 1 can be scattered, but also the material can be saved, the weight of the product can be reduced, and the production difficulty thereof can be reduced. It can be seen clearly from FIG. 3 that, the large beam of laser 6 with a high strength can be scattered into multiple small beams of laser 6.1 with a low strength by the scattering elements 3.2.

With respect to the shape of the scattering element 3.2, it can be seen clearly from FIG. 3 that, in a direction perpendicular to a surface of the flexible baseplate 2, a section of each scattering element 3.2 has a rectangle or a square shape (the specific shape as shown in FIG. 3 is just an example, and a ratio of an edge to an adjacent edge cannot be understood as a definition to the present embodiment). The scattering element with a rectangle or a square shape can be manufactured easily, and thus the manufacturing difficulty thereof can be simplified greatly. Moreover, since the scattering element has a rectangle or a square shape, the utilization rate of the material thereof is high. Therefore, the waste material can be effectively reduced, and the cost can be saved.

With respect to a width of the gap 8, in any direction of a surface of the flexible baseplate 2 (for example, a horizontal direction as shown in FIG. 3), a width of the gap 8 is ¼ to ½ a size of an adjacent scattering element 3.2 in a corresponding direction. In this manner, the laser energy coming from the glass substrate 1 can be scattered better. At the same time, a weight of the whole flexible board 100 or the manufacturing complexity thereof would not be increased excessively.

Of course, the scattering elements are not necessarily arranged as the above method, and can also be arranged in other methods. For example, the scattering elements 3.2 are arranged without gap thereamong. The scattering elements 3.2 are arranged adjacent to one another, and thus the plurality of scattering elements 3.2 as a whole can have a strong scattering effect on the laser 6 coming from the glass substrate 1.

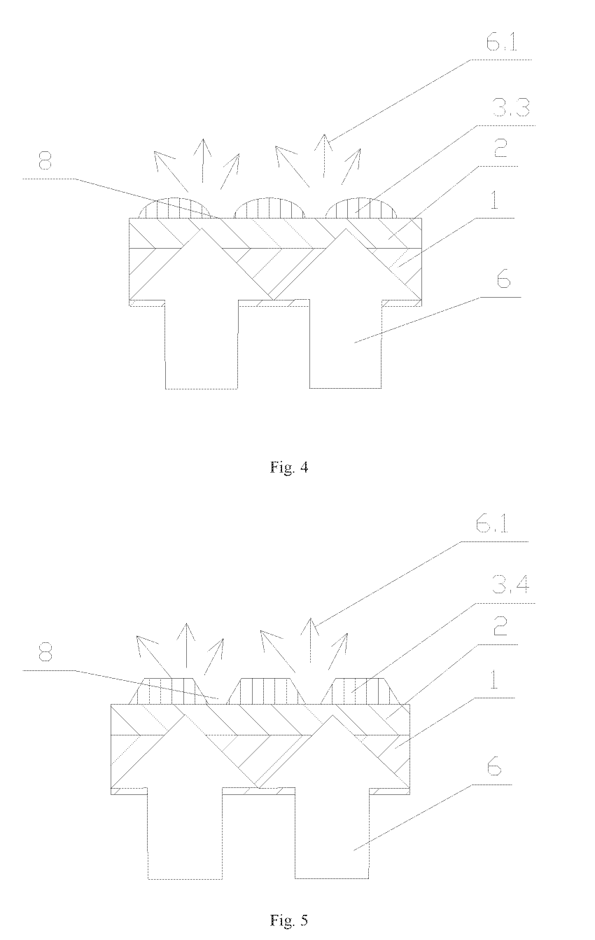

FIG. 4 schematically shows a partial structure of a flexible board according to a third embodiment of the present disclosure. According to the embodiment as shown in FIG. 4, on a surface of the flexible baseplate 2 where the scattering elements 3.3 are arranged (i.e., on the surface of the flexible baseplate 2 far from the glass substrate 1), the scattering elements 3.3 are arranged with gap 8 thereamong. In this manner, the arrangement mode of the scattering elements 3.3 can be regulated flexibly, so that not only the energy of the laser coming from the glass substrate 1 can be scattered, but also the material can be saved, the weight of the product can be reduced, and the production difficulty thereof can be reduced. It can be seen clearly from FIG. 4 that, the large beam of laser 6 with a high strength can be scattered into multiple small beams of laser 6.1 with a low strength by the scattering elements 3.3.

With respect to the shape of the scattering element 3.3, it can be seen clearly from FIG. 4 that, in a direction perpendicular to a surface of the flexible baseplate 2, a section of each scattering element 3.3 has a semielliptical or a semicircular shape (the specific shape as shown in FIG. 4 is just an example and cannot be understood as a definition to the present embodiment). A straight edge of the scattering element with a semielliptical or a semicircular shape is affixed to the surface of the flexible baseplate 2. The laser enters into the scattering element from the straight edge, and is scattered into a space containing a specific three-dimensional angle. The size of the three-dimensional angle is determined by an optical property of a material of the scattering element 3.3.

With respect to a width of the gap 8, in any direction of a surface of the flexible baseplate 2 (for example, a horizontal direction as shown in FIG. 4), a width of the gap 8 is ¼ to ½ a size of an adjacent scattering element 3.3 in a corresponding direction. In this manner, the energy of the laser coming from the glass substrate 1 can be scattered better. At the same time, a weight of the whole flexible board 100 or the manufacturing complexity thereof would not be increased excessively.

Of course, the scattering elements are not necessarily arranged as the above method, and can also be arranged in other methods. For example, the scattering elements 3.3 are arranged without gap thereamong. The scattering elements 3.3 are arranged adjacent to one another, and thus the plurality of scattering elements 3.3 as a whole can have a strong scattering effect on the laser 6 coming from the glass substrate 1.

FIG. 5 schematically shows a partial structure of a flexible board according to a fourth embodiment of the present disclosure. According to the embodiment as shown in FIG. 5, on a surface of the flexible baseplate 2 where the scattering elements 3.4 are arranged (i.e., on the surface of the flexible baseplate 2 far from the glass substrate 1), the scattering elements 3.4 are arranged with gap 8 thereamong. In this manner, the arrangement mode of the scattering elements 3.4 can be regulated flexibly, so that not only the energy of the laser coming from the glass substrate 1 can be scattered, but also the material can be saved, the weight of the product can be reduced, and the production difficulty thereof can be reduced. It can be seen clearly from FIG. 5 that, the large beam of laser 6 with a high strength can be scattered into multiple small beams of laser 6.1 with a low strength by the scattering elements 3.4.

With respect to the shape of the scattering element 3.4, it can be seen clearly from FIG. 5 that, in a direction perpendicular to a surface of the flexible baseplate 2, a section of each scattering element 3.4 has a trapezoid shape. A longer one of two parallel sides of the trapezoid is affixed to the surface of the flexible baseplate 2. In this manner, the scattering element 3.4 can be affixed to the flexible baseplate 2 securely. The laser enters into the scattering element 3.4 from the longer one of two parallel sides perpendicularly, and is scattered into a space with a specific size. The size of the space is determined by an optical property of a material of the scattering element 3.4 and angles of the trapezoid.

With respect to a width of the gap 8, in any direction of a surface of the flexible baseplate 2 (for example, a horizontal direction as shown in FIG. 5), a width of the gap 8 is ¼ to ½ a size of an adjacent scattering element 3.4 in a corresponding direction. In this manner, the energy of the laser coming from the glass substrate 1 can be scattered better. At the same time, a weight of the whole flexible board 100 or the manufacturing complexity thereof would not be increased excessively.

Of course, the scattering elements are not necessarily arranged as the above method, and can also be arranged in other methods. For example, the scattering elements 3.4 are arranged without gap thereamong. The scattering elements 3.4 are arranged adjacent to one another, and thus the plurality of scattering elements 3.4 as a whole can have a strong scattering effect on the laser 6 coming from the glass substrate 1.

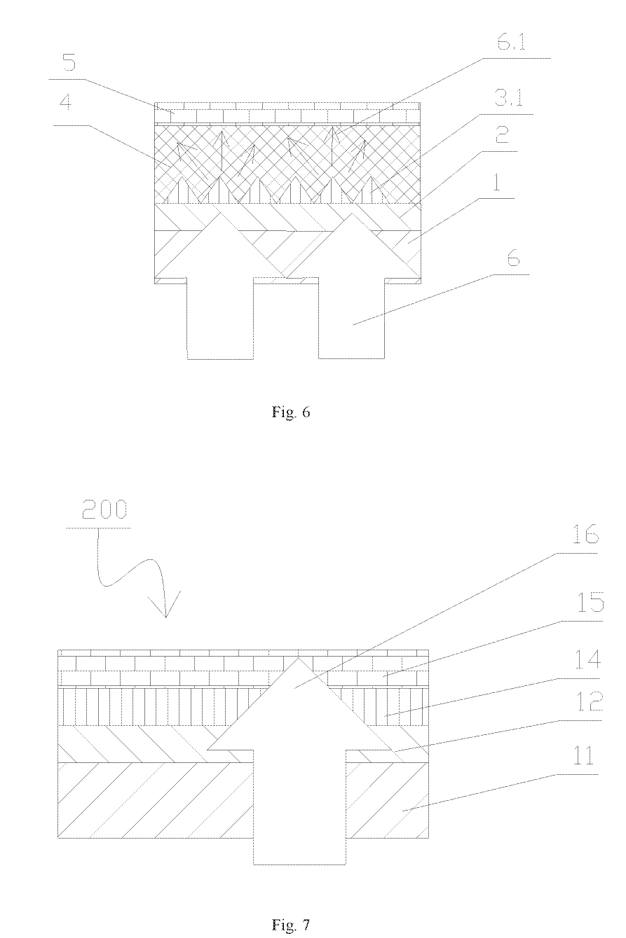

FIG. 6 is a laser transmission diagram in a flexible board according to a first embodiment of the present disclosure. It can be seen clearly from FIG. 6 that, when the flexible baseplate 2 is separated from an upper surface of the glass substrate 1 through the LLO technology, a large beam of laser 6 with a high strength enters into the glass substrate 1 from a lower surface thereof. The large beam of laser 6 passes through the glass substrate 1 and the flexible baseplate 2 so as to separate the flexible baseplate 2 from the glass substrate 1, and residual laser, after passing through the flexible baseplate 2, is scattered by the scattering structure that is arranged on the upper surface of the flexible baseplate 2. The scattering structure comprises a plurality of scattering elements 3.1 that are arranged adjacent to one another and have a triangle-shaped section and a nanometer to micrometer magnitude. The large beam of laser 6 with a high strength is scattered into multiple small beams of laser 6.1 with a low strength by the scattering elements 3.1. The small beams of laser 6.1 enter into the buffer layer 4 that is arranged at one side of the scattering structure 3.1 far from the flexible baseplate 2, and the laser attenuates gradually in the buffer layer 4.

According to the embodiment as shown in FIG. 6, the buffer layer 4 covers all of the scattering elements 3.1 and is filled in a space between adjacent scattering elements 3.1. With this arrangement, the buffer layer 4 can play its role better, because the laser exiting from any surface of the scattering elements 3.1 at any angle can all enter into the buffer layer 4 for attenuation. In a direction perpendicular to a surface of the flexible baseplate 2, a thickness of the buffer layer 4 is several times to thousands of times a size of the scattering element 3.1 in a corresponding direction. With this size arrangement, not only the energy of the scattered laser can be attenuated effectively, but also the thickness and weight of the flexible board 100 would not be increased excessively.

It can be seen from FIG. 6 that, the small beams of laser 6.1 attenuates gradually in the buffer layer 4 until disappear, and thus no laser arrives at the active layer 6 that is arranged at one side of the buffer layer 4 far from the flexible baseplate 2. Therefore, the active layer 5 is not damaged. Of course, according to the technical solution of the present disclosure, even if a small amount of laser arrives at the active layer 5 that is arranged at one side of the buffer layer 4 far from the flexible baseplate 2, it cannot do harm to the active layer 5, since the energy of the laser is reduced after scattering and attenuation.

The scattering elements can be formed on a surface of the flexible baseplate 2 through imprinting technology, photolithography technology, dry etching technology, or wet etching technology. It can be seen that, in the technical solution of the present disclosure, the specific manufacturing technology can be selected flexibly.

In order to prevent the active layer 5 from being damaged by the energy of the laser, the scattering element can also reflect or absorb light.

FIG. 7 is a laser transmission diagram in a flexible board 200 according to a comparative embodiment. According to the comparative embodiment, the flexible board 200 comprises a flexible baseplate 12, a buffer layer 14 that is arranged at one side of the flexible baseplate 12, and an active layer 15 that is arranged at one side of the buffer layer 14 far from the flexible baseplate 12. It can be seen clearly from FIG. 7 that, in the flexible board 200, no scattering structure is arranged for the scattering of the laser beam 16.

When the flexible baseplate 12 is separated from an upper surface of the glass substrate 11 through the LLO technology, a large beam of laser 16 with a high strength enters into the glass substrate 11 from a lower surface thereof. The large beam of laser 16 passes through the glass substrate 11 and the flexible baseplate 12 so as to separate the flexible baseplate 12 from the glass substrate 11, and residual laser, after passing through the flexible baseplate 12, enters into the buffer layer 14 that is arranged at one side of the flexible baseplate 12. The laser attenuates in the buffer layer 14 to a limited extent. However, due to the limitation of the manufacturing technology and the whole size of the flexible board 200, a thickness of the buffer layer 14 is limited rather than unlimited. When the buffer layer 14 in the flexible board 200 of the comparative embodiment and the buffer layer 4 in the flexible board 100 of the present disclosure have a same thickness, since the large beam of laser 16 has a rather high strength, it cannot attenuate in the buffer layer 14 until disappear or to a low enough extent. Part of the laser energy would enter into the active layer 15, and a structure of the active layer 15 would be destroyed by the large beam of laser due to a special property of laser. As a result, a product produced thereby would have a functional defect.

It can be seen that, the flexible board 100 according to the present disclosure has an apparent advantage in protecting the active layer.

The present disclosure is illustrated hereinabove with reference to the specific embodiments, which are only examples of the principle and use of the present disclosure. Those skilled in the art can make amendments to the embodiments disclosed herein or provide other arrangements without departing from the spirit and scope of the present disclosure. The technical feature described in one embodiment can also be used in other embodiments.

1. A flexible board, comprising:
a flexible baseplate;
a scattering structure that is arranged on at least one surface of the flexible baseplate;
a buffer layer that is arranged at one side of the scattering structure far from the flexible baseplate; and
an active layer that is arranged at one side of the buffer layer far from the flexible baseplate.

2. The flexible board according to claim 1, wherein the scattering structure comprises more than two scattering elements, and a size of each scattering element has a nanometer to micrometer magnitude.

3. The flexible board according to claim 2, wherein on a surface of the flexible baseplate where the scattering elements are arranged, the scattering elements are arranged without gap thereamong.

4. The flexible board according to claim 2, wherein on a surface of the flexible baseplate where the scattering elements are arranged, the scattering elements are arranged with gap thereamong.

5. The flexible board according to claim 4, wherein in any direction of a surface of the flexible baseplate, a width of the gap is ¼ to ½ a size of an adjacent scattering element in a corresponding direction.

6. The flexible board according to claim 2, wherein in a direction perpendicular to a surface of the flexible baseplate, a section of each scattering element has a triangle shape, a rectangle shape, a square shape, a semielliptical shape, a semicircular shape, or a trapezoid shape.

7. The flexible board according to claim 2, wherein the scattering elements are formed on a surface of the flexible baseplate through imprinting technology, photolithography technology, dry etching technology, or wet etching technology.

8. The flexible board according to claim 2, wherein the buffer layer covers all of the scattering elements and is filled in a space between adjacent scattering elements.

9. The flexible board according to claim 2, wherein in a direction perpendicular to a surface of the flexible baseplate, a thickness of the buffer layer is several times to thousands of times a size of the scattering element in a corresponding direction.

10. The flexible board according to claim 2, wherein the scattering element can also reflect or absorb light.
